(19) United States
(12) Patent Application Publication
(10) Pub. No.: US 2026/0006394 A1
(43) Pub. Date: Jan. 1, 2026

(54) Handling of Medium Absorption in Audio Rendering

(71) Applicant: Telefonaktiebolaget LM Ericsson (publ), Stockholm (SE)

(72) Inventor: Werner de Bruijn, Stockholm (SE)

(21) Appl. No.: 18/880,586

(22) PCT Filed: Jun. 15, 2023
(86) PCT No.: PCT/EP2023/066080

§ 371 Date: Jan. 2, 2025

Related U.S. Application Data
(60) Provisional application No. 63/358,847, filed on Jul. 6, 2022.

(51) Int. Cl. H04S 7/00; H03G 3/30

(52) U.S. Cl. CPC H04S 7/303; H03G 3/3089

(57) ABSTRACT

A method of rendering an audio source (22) for a listener (50). An audio renderer (40) determines a listening distance (30) that comprises a distance from which the listener (50) listens to the audio source (22). The audio renderer (40) determines a recording distance (20) that indicates a distance from which an audio signal (16) for the audio source (22) was recorded. The audio renderer (40) renders the audio source (22) based on the listening distance (30) and the recording distance (20). The audio renderer (40) for example calculates medium absorption gain value(s) (23) and applies the medium absorption gain value(s) (23) to the audio signal (16). For example, on a logarithmic (dB) scale, each medium absorption gain value (23) may be positive if the listening distance (30) is less than the recording distance (20) or negative if the listening distance (30) is greater than the recording distance (20).

### TECHNICAL FIELD

The present application relates generally to audio rendering, and relates more particularly to handling of medium absorption in audio rendering.

### BACKGROUND

Traditionally, spatial sound is represented in terms of channels associated with defined speaker positions, such that each channel is associated with a specific spatial meaning. In contrast to this channel-based content representation, object-oriented content representation represents spatial sound in terms of objects with associated metadata specifying the sound location and other object properties, e.g., which may be time-varying. As yet another way to represent spatial sound, higher-order ambisonics (HOA) describes an audio scene as a 3D acoustic sound field, represented as an expansion of the wavefield into harmonics.

No matter whether the source of audio includes channel(s), object(s), HOA signal(s), or some combination thereof, audio rendering refers to the process of rendering audio source(s) for presentation to a listener, e.g., for reproduction on the listener's loudspeakers or headphones. Audio rendering may for example be used to present audio within an extended reality (XR) scene, in order to give the listener the impression that sound is coming from sources within the scene at certain position(s).

Challenges exist in rendering audio in a way that sounds natural to the listener, especially in an XR context where the listener's location can change over time within the XR scene. For example, in some cases, the audio signal for an audio source is a recorded signal that was recorded from a real-life source, e.g., the virtual audio scene may include the sound of an airplane, and the audio signal representing the sound of the airplane may be a recording of an actual airplane. The recorded nature of the audio signal makes it difficult to render the audio source in a way that sounds natural to the listener, especially in an XR context where the listener moves within the audio scene.

### SUMMARY

Some embodiments herein render an audio source for a listener in a way that accounts for the recorded nature of the source's audio signal. Some embodiments in this regard render the audio source based on the distance from which the audio signal for the audio source was recorded, e.g., as well as the distance from which the listener listens to the audio source. For example, some embodiments herein render the audio source to simulate medium absorption over the listening distance, given medium absorption over the recording distance already represented in the audio signal. If the listening distance is the same as the recording distance, for instance, some embodiments herein refrain from simulating any medium absorption, since the audio signal as recorded already includes the impact of medium absorption over the listening distance. As another example, if the listening distance is more than the recording distance, some embodiments herein render the audio source to simulate medium absorption over only the difference between the listening distance and the recording distance, rather than over the full listening distance. By accounting for the distance from which the audio signal for the audio source was recorded, some embodiments herein avoid exaggerating the impact of medium absorption. Some embodiments thereby advantageously render an audio source in a way that sounds natural to the listener, even in an XR context where the listener moves within the audio scene.

More particularly, embodiments herein include a method of rendering an audio source for a listener. The method comprises determining a listening distance that comprises a distance from which the listener listens to the audio source. The method further comprises determining a recording distance that indicates a distance from which an audio signal for the audio source was recorded. The method further comprises rendering the audio source based on the listening distance and the recording distance.

In some embodiments, rendering the audio source comprises rendering the audio source to simulate medium absorption over the listening distance, given medium absorption over the recording distance already represented in the audio signal.

In some embodiments, rendering the audio source comprises controlling and/or applying medium absorption processing to the audio signal based on the listening distance and the recording distance.

In some embodiments, controlling medium absorption processing comprises making a decision as to whether or not to apply medium absorption processing to the audio signal, based on the listening distance and the recording distance. In this case, controlling medium absorption processing also comprises applying, or refraining from applying, medium absorption processing to the audio signal in accordance with the decision.

In some embodiments, making the decision comprises making the decision to apply medium absorption processing to the audio signal if the listening distance is greater than the recording distance. In this case, making the decision also comprises making the decision to refrain from applying medium absorption processing to the audio signal if the listening distance is less than or equal to the recording distance.

In some embodiments, applying medium absorption processing comprises calculating one or more medium absorption gain values as a function of the listening distance and the recording distance. In this case, applying medium absorption processing also comprises applying the one or more medium absorption gain values to the audio signal.

In some embodiments, calculating the one or more medium absorption gain values comprises calculating the one or more medium absorption gain values as a function of a difference between the listening distance and the recording distance.

In some embodiments, calculating the one or more medium absorption gain values comprises calculating the one or more medium absorption gain values to, on a logarithmic (dB) scale, each be zero if the listening distance is less than the recording distance, and negative if the listening distance is greater than the recording distance. Equivalently, on a linear scale, each medium absorption gain value may be calculated to be one if the listening distance is less than the recording distance or less than one if the listening distance is greater than the recording distance.

In some embodiments, calculating the one or more medium absorption gain values comprises calculating the one or more medium absorption gain values to, on a logarithmic (dB) scale, each be positive if the listening distance is less than the recording distance, and negative if the listening distance is greater than the recording distance. Equivalently, on a linear scale, each medium absorption gain value may be calculated to be greater than one if the listening distance is less than the recording distance or less than one if the listening distance is greater than the recording distance.

In some embodiments, the method further comprises, after applying the one or more medium absorption gain values to the audio signal to obtain a processed audio signal, applying noise reduction to the processed audio signal.

In some embodiments, the one or more medium absorption gain values comprise one or more medium absorption gain values for one or more respective frequencies.

In some embodiments, the one or more medium absorption gain values comprise one or more values of a gain function Gain(D,RD,f)=−AirAbs(D,RD,f) for the one or more respective frequencies f. In some embodiments, D is the listening distance and RD is the recording distance. In some embodiments, AirAbs(D,RD,f)=α(f)*(D−RD), where α(f) is a value of an absorption coefficient at a frequency f.

In some embodiments, applying the one or more medium absorption gain values to the audio signal comprises, if the listening distance is less than the recording distance, limiting or scaling the one or more medium absorption gain values, and applying the one or more medium absorption gain values, as limited or scaled, to the audio signal. In some embodiments, limiting the one or more medium absorption gain values comprises limiting the one or more medium absorption gain values to not exceed a maximum gain value. In some embodiments, limiting or scaling the one or more medium absorption gain values comprises limiting or scaling the one or more medium absorption gain values to an extent that depends on the listening distance.

In some embodiments, the method further comprises, before applying the one or more medium absorption gain values, applying audio bandwidth extension to the audio signal in order to synthesize one or more high frequency components in the audio signal.

In some embodiments, the audio source comprises the audio signal and metadata describing how to render the audio source from the audio signal. In some embodiments, determining the recording distance comprises determining the recording distance from one or more parameters included in the metadata. In some embodiments, the one or more parameters include a recording distance parameter that explicitly indicates the recording distance. In some embodiments, the one or more parameters include a medium absorption recording distance parameter that explicitly indicates a distance over which medium absorption is already represented in the audio signal.

In some embodiments, the audio signal is a recording of a source audio signal as recorded from the recording distance. In some embodiments, determining the recording distance comprises determining the recording distance based on comparing one or more characteristics of the audio signal to the same one or more characteristics of the source audio signal.

In some embodiments, determining the recording distance comprises determining the recording distance based on comparing one or more characteristics of the audio signal to the same one or more characteristics of a reference audio signal. In some embodiments, the audio source comprises the audio signal and metadata describing how to render the audio source from the audio signal. In some embodiments, determining the recording distance comprises determining the recording distance according to an ordering of candidate determination options. In some embodiments, the candidate determination options include at least a medium absorption recording distance parameter in the metadata that explicitly indicates a distance over which medium absorption is already represented in the audio signal. In other embodiments, the candidate determination options additionally or alternatively include at least a recording distance parameter in the metadata that explicitly indicates the recording distance corresponding to the audio signal. In yet other embodiments, the candidate determination options additionally or alternatively include at least a comparison of one or more characteristics of the audio signal to the same one or more characteristics of a reference audio signal. In some embodiments, the medium absorption recording distance parameter is ordered by the ordering before the recording distance parameter. In some embodiments, the recording distance parameter is ordered by the ordering before the comparison.

In some embodiments, the audio source comprises one or more audio channels. In other embodiments, the audio source alternatively or additionally comprises one or more audio objects. In yet other embodiments, the audio source alternatively or additionally comprises one or more higher-order ambisonic, HOA, signals. In yet other embodiments, the audio source alternatively or additionally comprises any combination thereof.

In some embodiments, rendering the audio source is performed as part of rendering audio of an extended reality application.

In some embodiments, rendering the audio source comprises rendering the audio source into an audio output signal. In some embodiments, the method further comprises providing the audio output signal for playback to the listener. In some embodiments, the audio output signal is a binaural signal.

In some embodiments, the method further comprises receiving an audio stream that encapsulates the audio source as an audio object with associated metadata about how to render the audio object. In some embodiments, the audio stream is an MPEG-H 3D audio stream or MPEG-I Immersive Audio stream.

In some embodiments, the method is performed by audio rendering equipment.

In some embodiments, the method is performed by an audio renderer.

Other embodiments herein include a method comprising obtaining an audio signal for an audio source. In this case, the method further comprises generating metadata that describes how the audio source is to be rendered. In some embodiments, the metadata is generated to include one or more parameters that indicate a recording distance. In some embodiments, the recording distance indicates a distance from which the audio signal for the audio source was recorded. In this case, the method further comprises encapsulating, in an audio stream, the audio source as an audio object that includes the audio signal and the generated metadata. In this case, the method further comprises outputting the audio stream with the audio source encapsulated therein.

In some embodiments, the one or more parameters include a recording distance parameter that explicitly indicates the recording distance.

In some embodiments, the one or more parameters include a medium absorption recording distance parameter that explicitly indicates a distance over which medium absorption is already represented in the audio signal.

In some embodiments, the audio source is an audio source of an extended reality application.

In some embodiments, the audio stream is an MPEG-H 3D audio stream or MPEG-I Immersive Audio stream.

In some embodiments, the method is performed by an audio encoder.

Embodiments herein also include corresponding apparatus, computer programs, and carriers of those computer programs. For example, embodiments herein further include an audio renderer for rendering an audio source for a listener. The audio renderer may for instance be an audio renderer of a communication device. Regardless, the audio renderer is configured to determine a listening distance that comprises a distance from which the listener listens to the audio source. The audio renderer may further be configured to determine a recording distance that indicates a distance from which an audio signal for the audio source was recorded. The audio renderer may also be configured to render the audio source based on the listening distance and the recording distance.

The audio renderer for example calculates medium absorption gain value(s) and applies the medium absorption gain value(s) to the audio signal. For example, on a logarithmic (dB) scale, each medium absorption gain value may be positive if the listening distance is less than the recording distance or negative if the listening distance is greater than the recording distance.

### BRIEF DESCRIPTION OF FIGURES

FIG. 1A is a block diagram of an audio source according to some embodiments.

FIG. 1B is a block diagram of a recording of an audio signal of an audio source according to some embodiments.

FIG. 1C is a block diagram of an audio renderer according to some embodiments.

FIG. 2 is a block diagram of an audio renderer according to other embodiments.

FIG. 3 is a block diagram of an audio renderer according to still other embodiments.

FIG. 4 is a block diagram of an audio renderer according to yet other embodiments.

FIG. 5 is an example curve for the air absorption coefficient ox as function of frequency according to some embodiments.

FIG. 6 is an example plot of the attenuation AirAbs as function of distance from the source according to some embodiments.

FIG. 7 is an example plot of attenuation with recording distance according to some embodiments.

FIG. 8 is an example plot of air absorption gain according to some embodiments.

FIG. 9 is an example plot of air absorption gain according to other embodiments.

FIG. 10 is a logic flow diagram of a method performed by an audio renderer according to some embodiments.

FIG. 11 is a logic flow diagram of a method performed by an audio encoder according to some embodiments.

FIG. 12 is a block diagram of an audio renderer according to some embodiments.

FIG. 13 is a block diagram of an audio encoder according to some embodiments.

FIG. 14 is a block diagram of a system incorporating an audio renderer according to some embodiments.

FIG. 15A is a block diagram of an XR system according to some embodiments.

FIG. 15B is a block diagram of details of the XR system of FIG. 15A according to some embodiments.

### DETAILED DESCRIPTION

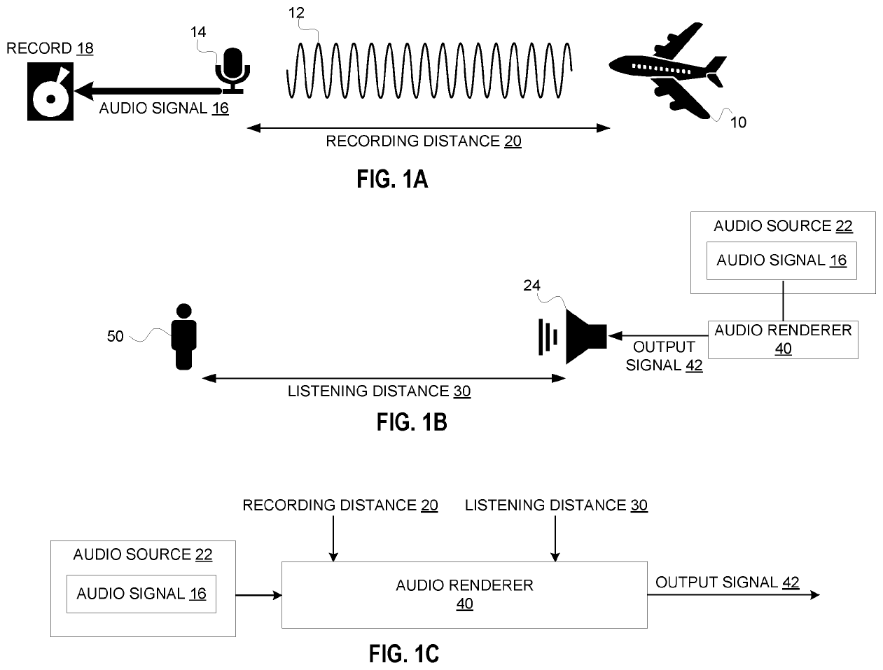

Some embodiments herein provide audio rendering for an audio source whose audio signal was recorded as shown in FIG. 1A. FIG. 1A in this regard shows that a source 10 (e.g., an airplane) produces a sound 12 (also referred to as a source audio signal). A microphone 14 captures this sound 12, from a distance 20, as an audio signal 16. This audio signal 16 is recorded on a record 18, e.g., in the form of computer memory or storage. The distance 20 between the source 10 and the microphone 14 is therefore appropriately referred to as the recording distance 20, since the distance 20 is the distance from which the audio signal 16 was recorded. Some embodiments herein advantageously provide audio rendering that accounts for this recording distance 20.

FIG. 1B illustrates audio rendering according to some embodiments. As shown, the audio signal 16 that was recorded in FIG. 1A is an audio signal for an audio source 22. In some embodiments, the audio source 22 may be one or more audio channels, one or more audio objects, one or more higher-order ambisonic, HOA, signals, or any combination thereof. In any event, an audio renderer 40 renders the audio source 22 for a listener 50. The audio renderer 40 as shown in this regard renders the audio source 22 into an output signal 42 that represents sound of the audio source 22 as originating from a source position 24. That is, the audio renderer 40 renders the audio source 22 so that the listener 50 has the impression that the sound of the audio source 22 comes from the source position 24. This source position 24 may be a physical position or a virtual position. No matter whether the source position 24 is physical or virtual, FIG. 1B shows that the listener 50 listens to the audio source 22 at a distance 30 referred to as the listening distance 30. The listening distance 30 in this case is the distance between the listener 50 and the physical or virtual position 24 associated with the audio source 22.

For example, in embodiments where the audio renderer 40 is part of an extended reality (XR) system and the listener 50 is a user of the XR system, the audio renderer 40 may render the audio source 22 as part of rendering audio of an XR application. In this case, the audio renderer 40 may render the audio source 22 so that, in the XR sound scene, the listener 50 has the impression that the sound of the audio source 22 comes from a certain virtual position in the XR sound scene. The listening distance 30 in this case is the distance between the virtual position of the listener 50 and the virtual position from which sound of the audio source 22 originates. In an XR system, this listening distance 30 may change over time as the listener virtually moves.

In any event, whether or not the audio renderer 40 is part of an XR system, FIG. 1C shows that the audio renderer 40 according to some embodiments renders the audio source 22 based on the recording distance 20. In one or more embodiments, the audio renderer 40 renders the audio source 22 based also on the listening distance 30.

For example, the audio renderer 40 in some embodiments renders the audio source 22 to simulate medium (e.g., air) absorption over the listening distance 30, given medium absorption over the recording distance 20 already represented in the audio signal 16. That is, because the audio signal 16 was recorded at the recording distance 20, that audio signal 16 already includes the impact of medium absorption over the recording distance 20. Accordingly, rather than rendering the audio source 22 as if the audio signal 16 had not already been impacted by some medium absorption, the audio renderer 40 in embodiments herein simulates medium absorption in a way that accounts for the impact that medium absorption has already had on the audio signal 16 due to its recorded nature.

If the listening distance 30 is the same as the recording distance 20, for instance, the audio renderer 40 in some embodiments herein refrains from simulating any medium absorption, since the audio signal 16 as recorded already includes the impact of medium absorption over the listening distance 30. As another example, if the listening distance 30 is more than the recording distance 20, the audio renderer 40 in some embodiments herein renders the audio source 22 to simulate medium absorption over only the difference between the listening distance 30 and the recording distance 20, rather than over the full listening distance 30.

In another example, where the source position 24 is a physical position (e.g., loudspeaker), then in the rendering process there is physical air absorption over the listening distance 30. So, in that case, there is effectively air absorption over the total distance (recording distance+listening distance) in the absence of any active air absorption processing. To then achieve the effect of air absorption over the listening distance 30 only, some embodiments compensate for (invert) the air absorption over the recording distance 20. The listening distance 30 plays no role in this case.

By accounting for the distance from which the audio signal 16 for the audio source 22 was recorded, some embodiments herein avoid exaggerating the impact of medium absorption. Some embodiments thereby advantageously render the audio source 22 in a way that sounds natural to the listener 50, even in an XR context where the listener 50 moves within the audio scene.

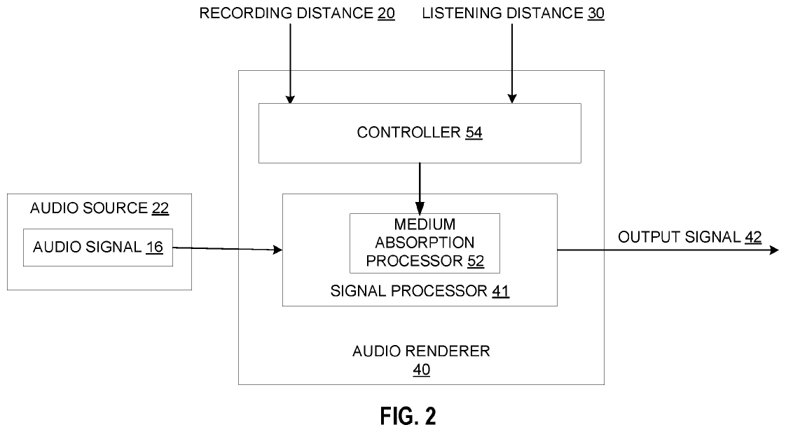

FIG. 2 illustrates some additional details of some embodiments herein. As shown, the audio renderer 40 includes a controller 54 and a signal processor 41. The signal processor 41 applies processing to the audio signal 16 for the audio source 22 as part of rendering the audio source 22 into the output signal 42. This processing includes medium absorption processing as applied by a medium absorption processor 52, where medium absorption processing involves applying one or more medium absorption gain values to the audio signal 16. Medium absorption processing may be exemplified as air absorption processing, e.g., via air absorption filtering. Regardless, the controller 54 controls the signal processing applied by the signal processor 41, including the medium absorption processing applied by the medium absorption processor 52.

In some embodiments, the controller 54 controls medium absorption processing by the medium absorption processor 52 based on the listening distance 30 and the recording distance 20. For example, in one embodiment, the controller 54 makes a decision as to whether or not to apply medium absorption processing to the audio signal 16, based on the listening distance 30 and the recording distance 20. In one such embodiment, the controller 54 makes the decision to apply medium absorption processing to the audio signal 16 if the listening distance 30 is greater than the recording distance 20. On the other hand, the controller 54 makes the decision to refrain from applying medium absorption processing to the audio signal 16 if the listening distance 30 is less than or equal to the recording distance 20. Regardless, the medium absorption processor 52 accordingly applies, or refrains from applying, medium absorption processing to the audio signal 16 in accordance with the decision.

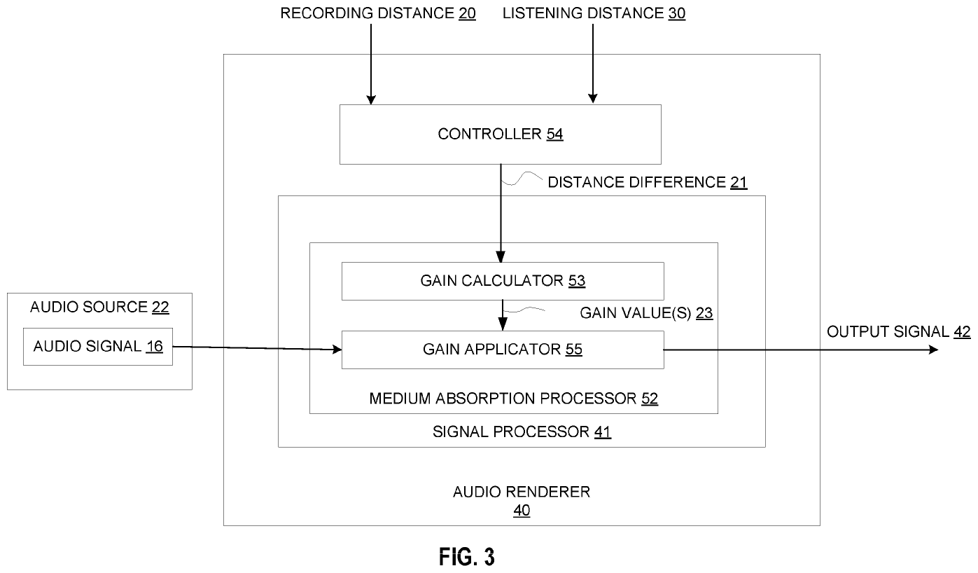

Alternatively or additionally, in some embodiments, the medium absorption processor 52 applies medium absorption processing to the audio signal 16 based on the listening distance 30 and the recording distance 20. For example, the medium absorption gain value(s) applied to the audio signal 16 may be calculated as a function of the listening distance 30 and the recording distance 20. FIG. 3 shows one example in this regard.

As shown in FIG. 3, the controller 54 computes a difference 21 between the listening distance 30 and the recording distance 20, e.g., as the listening distance 30 minus the recording distance 20. The medium absorption processor 52 includes a gain calculator 53 that calculates medium absorption gain value(s) 23 as a function of this difference 21. For example, the gain calculator 53 may calculate the medium absorption gain value(s) 23 to, on a logarithmic (dB) scale, each be zero if the listening distance 30 is less than the recording distance 20 (e.g., the difference 21 is negative) and negative if the listening distance 30 is greater than the recording distance 20 (e.g., the difference 21 is positive). Or, in another example, the gain calculator 53 may calculate the medium absorption gain value(s) 23 to, on a logarithmic (dB) scale, each be positive if the listening distance 30 is less than the recording distance 20 (e.g., the difference 21 is negative) and negative if the listening distance 30 is greater than the recording distance 20 (e.g., the difference 21 is positive). Regardless, the medium absorption processor 52 as shown further includes a gain applicator 55 that applies the medium absorption gain value(s) 23.

Note that, in some embodiments, the medium absorption gain value(s) 23 comprise one or more medium absorption gain values for one or more respective frequencies. For example, in one embodiment where the medium absorption gain value(s) 23 are air absorption gain value(s), the medium absorption gain value(s) 23 comprise one or more values of a gain function Gain(D,RD,f)=−AirAbs(D,RD,f) for the one or more respective frequencies f, where D is the listening distance 30 and RD is the recording distance 20. As an example, AirAbs(D,RD,f)=α(f)+ (D−RD), where α(f) is a value of an absorption coefficient at a frequency f.

Note that, in some embodiments, the medium absorption gain value(s) 23 may be a subset of all medium absorption gain values calculated by the medium absorption processor 52. For example, the medium absorption gain value(s) 23 may be for a subset of frequencies.

Consider now additional details for how the audio renderer 40 determines the recording distance 20. In some embodiments, the audio source 22 comprises the audio signal 16 as well as metadata describing how to render the audio source 22 from the audio signal 16. In one such embodiment, the audio renderer 40 may determine the recording distance 20 from one or more parameters included in the metadata. For example, the parameter(s) may include a recording distance parameter that explicitly indicates the recording distance 20, e.g., for use in any part of rendering the audio source 22. Or, the parameter(s) may include a medium absorption recording distance parameter that explicitly indicates a distance over which medium absorption is already represented in the audio signal 16, e.g., for use specifically in controlling and/or applying medium absorption processing to the audio signal 16.

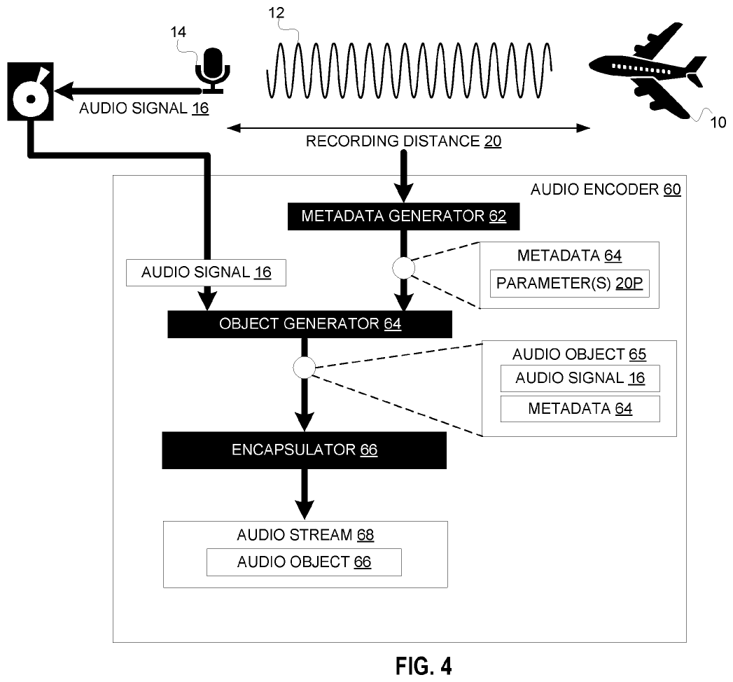

FIG. 4 illustrates one example for how the metadata can be generated to include such parameter(s) for indicating the recording distance 20. As shown in FIG. 4, an audio encoder 60 includes a metadata generator 62. The metadata generator 62 generates metadata 64 describing how the audio source 22 is to be rendered. The metadata generator 62 generates the metadata 64 to include one or more parameters 20P that indicate the recording distance 20. The parameter(s) 20P may for instance include a recording distance parameter or a medium absorption recording distance parameter as described above. The audio encoder 60 includes an object generator 64 that generates the audio source 22 as an audio object 65 that includes the audio signal 16 and the metadata 64. The audio encoder 60 further includes an encapsulator 66 that encapsulates this audio object 65 in an audio stream 68, e.g., an MPEG-H 3D audio stream or MPEG-I Immersive Audio stream. The audio encoder 60 correspondingly outputs this audio stream 68, e.g., for storage or transmission towards the audio renderer.

Consider now some examples of embodiments herein in a context where medium absorption is exemplified as air absorption and where the sound of an audio source is rendered to a user of, e.g., a VR or AR system. In this case, one aspect that can contribute to the perceived realism of the audio experience is the inclusion of the effect of distance attenuation due to medium (e.g., air) absorption.

Medium absorption as used herein refers to the following. In the physical world, when the sound that is radiated by a sound source propagates away from the source through the air, a small fraction of the energy of the propagating sound waves is constantly converted into heat, i.e., is dissipated as a result of the propagation through the air. Another way of expressing this is that part of the energy is absorbed by the air that the sound travels through. This air absorption (also called “atmospheric absorption”) process consists of several physical processes (most significantly: viscous losses due to friction between air molecules, and a quantum-mechanical relaxation effect) that combine to result in an overall frequency-dependent filtering of the source signal, where generally speaking the filtering is stronger for higher frequencies. In this way, the overall effect of the air absorption can be seen as a low-pass filtering effect on the sound, the effect of which becomes more significant as the distance from the source increases. So, while at short distances to the source there may not be any perceivable effect from the air absorption filtering, at a large distance from the source there may be a clearly perceptible effect where the timbral characteristic of the sound has changed such that many of the high frequencies have been removed so that mainly a dull, low-frequency dominated sound remains.

Some embodiments herein exploit one or more models for modeling the effect of air absorption as a function of distance. In some embodiments, the model(s) also depend on environmental parameters like air temperature, humidity, atmospheric pressure, etc.

Some embodiments in particular exploit a model of the form:

$$AirAbs ( r , f ) ∝ α ( f ) * r , \qquad ( 1 )$$

where AirAbs is the attenuation due to air absorption (expressed in dB) at a distance r from the source and at frequency f, and a is the absorption coefficient (e.g., expressed in dB/100 m) that depends on atmospheric parameters. The absorption coefficient α is a positive number, so AirAbs indicates the number of dB's by which the source signal level is reduced at frequency f due to the air absorption.

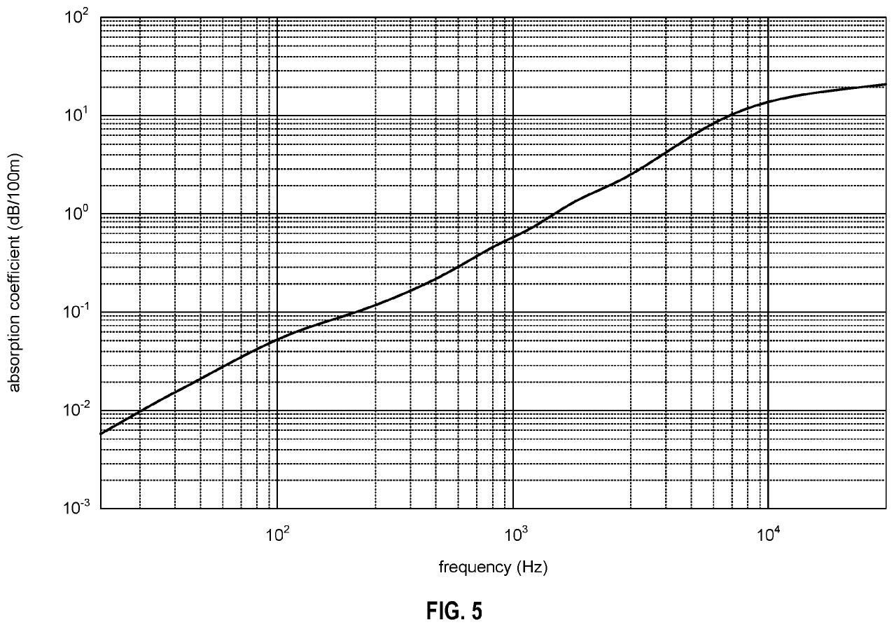

FIG. 5 shows an example curve for the air absorption coefficient ox as function of frequency according to some embodiments.

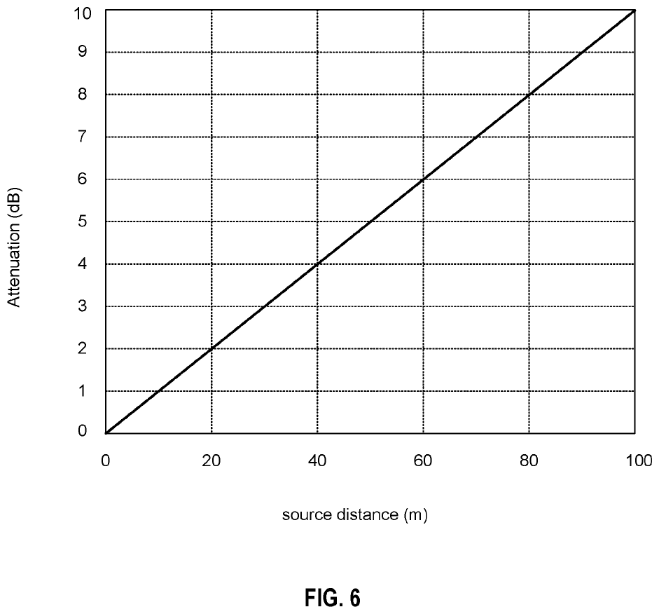

FIG. 6 shows an example of the attenuation AirAbs as function of distance from the source according to equation 1 for a value of the absorption coefficient α=10 dB/100 m. in the example of FIG. 5, the absorption coefficient xx may correspond to a frequency of about 4 KHz.

Alternatively or additionally, some embodiments herein exploit a modified version of a model for air absorption specified by a standard, e.g., American National Standards Institute (ANSI) Standard S1-26:1995 and/or ISO 9613-1:1996 and/or the Moving Picture Experts Group I (MPEG-I) Immersive Audio standard. The modified version of the model in this regard advantageously accounts for not only the distance of the listener from the source but also the recording distance.

Some embodiments thereby address a scenario where the audio signal for an audio source (e.g., an airplane) already includes the effect of air absorption corresponding to the propagation path from the physical source (the airplane) to the position from where the audio signal was recorded. Some embodiments in this regard render the audio source in such a way as to avoid processing the audio signal with an air absorption filter model that simply uses the (virtual) distance to the (virtual) audio source as control parameter (which would effectively apply two air absorption filtering processes on top of each other (one physical, one artificial)). Some embodiments thereby avoid an exaggerated air absorption effect in the rendered signal, which would not be natural or desirable. Generally, some embodiments accomplish this by making the effect of air absorption for a rendered audio source dependent on a parameter that indicates the recording distance of the source signal corresponding to the audio source.

### “Recording Distance” Source Parameter

Consider now some examples of parameter(s) 20P in FIG. 4 that may indicate the recording distance 20.

To enable the audio renderer 40 to correctly apply the air absorption effect, i.e., to avoid the described problem of “double” application of air absorption, a “recording distance” parameter may be included in the metadata 64 corresponding to the source. The recording distance parameter may specify or indicate the distance 20 from the source 22 at which the corresponding source signal 16 was recorded (either in real-life, or in a simulation).

The recording distance parameter may take many forms. For example, the parameter may be an explicit “recording distance” parameter associated with the audio signal 16 corresponding to the audio source 22. Such recording distance metadata parameter, which might, e.g., be called recordingDistance, may be added to the existing MPEG-I Immersive Audio RMO bitstream syntax for the various types of audio sources, and/or to the existing MPEG-I Immersive Audio Encoder Input Format (EIF), e.g., as shown below for an audio source of the type “ObjectSource”.

Example MPEG-I Immersive Audio Encoder Input Format Syntax for Audio Element of Type “ObjectSource”, with Addition of Example “Recording Distance” Parameter:

<ObjectSource>

Declares an ObjectSource which emits sound into the virtual scene. The ObjectSource has a
position/orientation in space. The radiation pattern can be controlled by a directivity. If no
directivity attribute is present, the source radiates omnidirectional. Optionally it can have a
spatial extent, which is specified through a geometric object. If no extent is specified, the
source is a point source. Optionally, the ObjectSource can have a recording distance, which
indicates the distance at which the signal component of the ObjectSource was recorded. The
signal component of the ObjectSource must contain at least one waveform. When the signal
has multiple waveforms, the spatial layout of these waveforms must be specified in an
<InputLayout> subnode.

| Child node | Count | Description |
|---|---|---|
| <InputLayout> | 0 . . . 1 | Signal positioning (required when signal |
| | | has multiple waveforms) |

| Attribute | Type | Flags | Default | Description |
|---|---|---|---|---|
| Id | ID | R | | Identifier |
| position | Position | R, M | | Position |
| orientation | Rotation | O, M | (0° 0° 0°) | Orientation |
| cspace | Coordinate | O | relative | Spatial frame of reference |
| | space | | | |
| active | Boolean | O, M | true | If true, then render this source |
| gainDb | Gain | O, M | 0 | Gain (dB) |
| refDistance | Float > 0 | O | 1 | Reference distance (m) (see comment |
| | | | | below) |
| signal | AudioStream ID | R, M | | Audio stream |
| recordingDistance | Float > 0 | O, M | none | Recording distance of signal |
| extent | Geometry ID | O, M | none | Spatial extent |
| directivity | Directivity ID | O, M | none | Sound radiation pattern |
| directiveness | Value | O, M | 1 | Directiveness |
| aparams | Authoring | O | none | Authoring parameters |
| | parameters | | | |
| mode | Playback mode | O | continuous | Playback mode {“continuous”, “event”} |
| play | Boolean | O, M | False | Playback enabled? |

Example MPEG-I Immersive Audio Bitstream Syntax for Audio Element of Type “ObjectSource”, with Addition of Example “Recording Distance” Parameter:

TABLE 1
Syntax of objectSources( )

| Syntax | No. of bits | Mnemonic |
|---|---|---|
| objectSources( ) | | |
| { | | |
| objectSourcesCount; | 16 | uimsbf |
| for (int i = 0; i < objectSourcesCount; i++) { | | |
| hasInputLayout; | 1 | bslbf |
| if (hasInputLayout) { | | |
| inputLayoutAlignment; | 1 | bslbf |
| inputLayoutTL; | 1 | bslbf |
| inputLayoutT; | 1 | bslbf |
| inputLayoutTR; | 1 | bslbf |
| inputLayoutL; | 1 | bslbf |
| inputLayoutC; | 1 | bslbf |
| inputLayoutR; | 1 | bslbf |
| inputLayoutBL; | 1 | bslbf |
| inputLayoutB; | 1 | bslbf |
| inputLayoutBR; | 1 | bslbf |
| } | | |
| objectSourceId; | 16 | uimsbf |
| objectSourcePositionX; | 32 | float |
| objectSourcePositionY; | 32 | float |
| objectSourcePositionZ; | 32 | float |
| objectSourceOrientationYaw; | 32 | float |
| objectSourceOrientationPitch; | 32 | float |
| objectSourceOrientationRoll; | 32 | float |
| objectSourceCoordSpace; | 1 | bslbf |
| objectSourceActive; | 1 | bslbf |
| objectSourceGainDb; | 12 | uimsbf |
| objectSourceRefDistance; | 10 | Uimsbf |
| objectSourceRecordingDistance; | 10 | Uimsbf |
| objectSourceSignalId; | 16 | uimsbf |
| objectSourceHasExtent; | 1 | bslbf |
| if (objectSourceHasExtent) { | | |
| objectSourceExtentId; | 16 | uimsbf |
| } | | |
| objectSourceHasDirectivity; | 1 | bslbf |
| if (objectSourceHasDirectivity) { | | |
| objectSourceDirectivityId; | 16 | uimsbf |
| } | | |
| objectSourceDirectiveness; | 8 | uimsbf |
| objectSourceNoReverb; | 1 | bslbf |
| objectSourceNoDoppler; | 1 | bslbf |
| objectSourceNoDistance; | 1 | bslbf |
| objectSourceMode; | 1 | bslbf |
| objectSourcePlay; | 1 | bslbf |
| objectSourceHasSpatialTransform; | 1 | bslbf |
| if (objectSourcehasSpatialTransform){ | | |
| objectSourceHasAnchor; | 1 | bslbf |
| if (objectSourceHasAnchor){ | | |
| objectSourceParentAchorId; | 16 | uimsbf |
| } | | |
| else { | | |
| objectSourceParentTransformId; | 16 | uimsbf |
| } | | |
| } | | |
| objectSourcelsStatic; | 1 | bslbf |
| } | | |
| } | | |

As another example, the parameter may come in the form of a specific “air absorption recording distance” parameter or similar, which may directly specify the distance range from the source for which the effect of air absorption is already included in the source signal. The reason for having this specific parameter instead of, or in addition to, the general “recording distance” parameter is that, although the two should in principle be the same from a physics perspective, there may be reasons, e.g., artistic reasons, to set or treat the two parameters differently. For example, the general “recording distance” parameter may also be used to control other rendering aspects for the source, e.g., spatial rendering aspects for the source.

In absence of a recording distance parameter, i.e., if no explicit (air absorption) recording distance parameter is provided for the audio source, the audio renderer 40 may be configured to assume that the audio signal 16 associated with the audio source 22 was recorded close to the source, i.e., the renderer 40 may set the value of the recording distance to 0 or, more generally, process the source as if the recording distance is 0.

The recording distance parameter does not necessarily have to be labelled explicitly as such, and it may in fact be a parameter that is also (or even primarily) used for other purposes by the audio renderer 40. In the context of the effect of air absorption, though, the parameter may be interpreted to effectively have the meaning of a recording distance, or at least be sufficiently related to it.

Alternatively, the recording distance may be determined or estimated in other ways, e.g., directly from the provided source signal itself. For example, if the characteristics (e.g., spectrum, level) of the original source signal are known (i.e., the characteristics of the signal close to the source), then the recording distance may be determined from comparing the characteristics of the provided source signal to those of the original source signal. This may be the case for instance where the source is voice, which has well-defined characteristic(s) usable for this purpose.

In some embodiments, the renderer may be configured to apply a hierarchical selection scheme in selecting a specific one out of the various forms of the recording distance parameter that it supports and that may be available to it, to be used for the purpose of controlling the air absorption processing. For example, the audio renderer 40 may be configured to always use the explicit “air absorption distance” parameter if it has been provided for the audio source 22. If that has not been provided, then the audio renderer 40 is configured to use the explicit “recording distance” parameter if that has been provided. If that also has not been provided, the audio renderer 40 may use another suitable parameter that has been provided. Finally, if none of these have been provided, the audio renderer 40 may estimate the recording distance from the provided audio signal 16 associated with the source. Other sets and orderings than in this example are possible and depend on the renderer implementation and/or audio format (e.g., standard) of the audio content.

### Applying the Recording Distance Parameter

In one embodiment, the recording distance parameter, RD, may be applied such that the air absorption filtering is only applied starting from the recording distance 20, i.e., it is only applied at distances larger than RD to the corresponding source.

This may be achieved by calculating the air absorption filtering effect to be applied to the source signal using a modified distance D_mod=D−RD, where D is the actual distance to the source and D_mod is the modified distance.

The effect of this is that the “origin” of the air absorption process is shifted from D=0 (the source position) to D=RD (the recording distance 20).

So, if AirAbs(r,f) is the function that models the attenuation due to air absorption at a distance r from the source at frequency f, e.g., according to equation 1, then the function AirAbs may be evaluated at the modified distance D_mod=D−RD instead of the actual distance D. An equivalent way to view this, is that the air absorption attenuation function has been modified, i.e., in the specific example of the air absorption model according to equation 1:

$$AirAbs ( D , RD , f ) = α ( f ) * {D}_{m o d} = α ( f ) * ( D - RD ) . \qquad ( 2 )$$

In one embodiment, no air absorption filtering processing is applied to the source at all at distances smaller than RD, i.e., between the source position and the recording distance RD the source signal is used “as is” (at least in the context of air absorption. Other effects may of course still be applied to the signal in this region).

This “do not apply air absorption processing” at distances smaller than RD may be practically achieved in several ways.

One way is to make the processing logic such that the air absorption processing functionality is simply bypassed when D<RD.

Another way to achieve the same effect is to restrict the value of D_mod to never be smaller than zero, i.e.:

$${D}_{m o d} = \{ \begin{matrix}0 & D < RD \\ D - RD & D \geq RD\end{matrix} . \qquad ( 3 )$$

So, whenever D becomes smaller than RD, the air absorption filtering that is applied is the same as at D=0, i.e., effectively no air absorption filtering is applied. The same effect may be achieved by:

$$AirAbs ( D , R D , f ) = \{ \begin{matrix}AirAbs ( 0 ) & {D}_{m o d} < 0 \\ AirAbs ( {D}_{m o d} ) & {D}_{m o d} \geq 0\end{matrix} . \qquad ( 4 )$$

Note that, with the embodiments described above, at distances smaller than the recording distance 20, the air absorption effect is fixed to the effect of air absorption that is included in the source signal, i.e., the effect corresponding to the recording distance 20, and does not change with distance within this distance region as it would for a real sound source.

Instead of bypassing or neutralizing the air absorption filtering for distances smaller than the recording distance 20 as in the embodiments above, other embodiments herein invert the effect of the air absorption filtering to the source signal in this region. In other words, for distances smaller than the recording distance 20, a filtering is applied that increases the signal level at higher frequencies rather than decreasing it.

This effect may be achieved by allowing D_mod=D−RD in equation (2) to become negative.

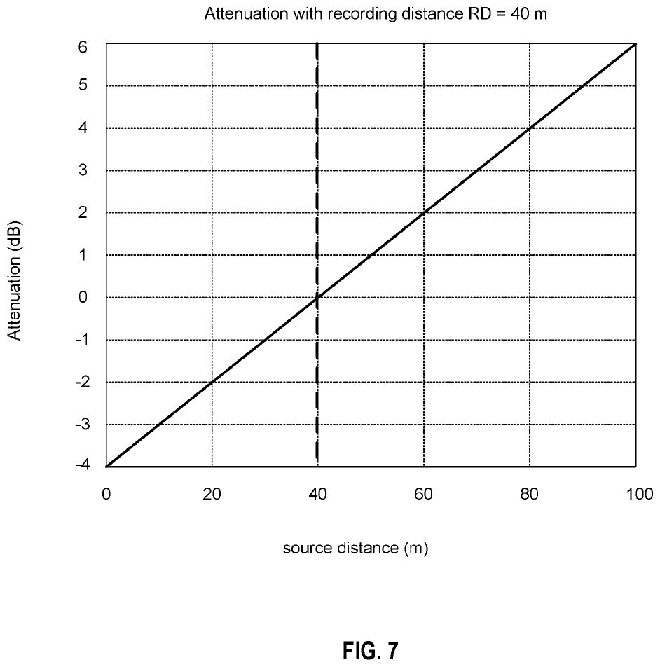

FIG. 7 shows an example for α=10 dB/100 m and RD=40 m. Comparing FIG. 7 to FIG. 6 shows that the attenuation curve of FIG. 6 has been shifted to the right by a distance of RD, and becomes negative for distances smaller than RD, i.e., the attenuation is in fact an amplification in that region.

In some embodiments described above, the attenuation is calculated at various frequencies, and finally a frequency-dependent gain (i.e., a filter) is derived that is applied to the audio source signal to achieve the desired air absorption filtering effect. Here, a positive value of the attenuation corresponds to a negative value of the gain, and vice versa, so the frequency-dependent gain may be derived as:

$$Gain ( D , RD , f ) = - AirAbs ( D , RD , f ) \qquad ( 5 )$$

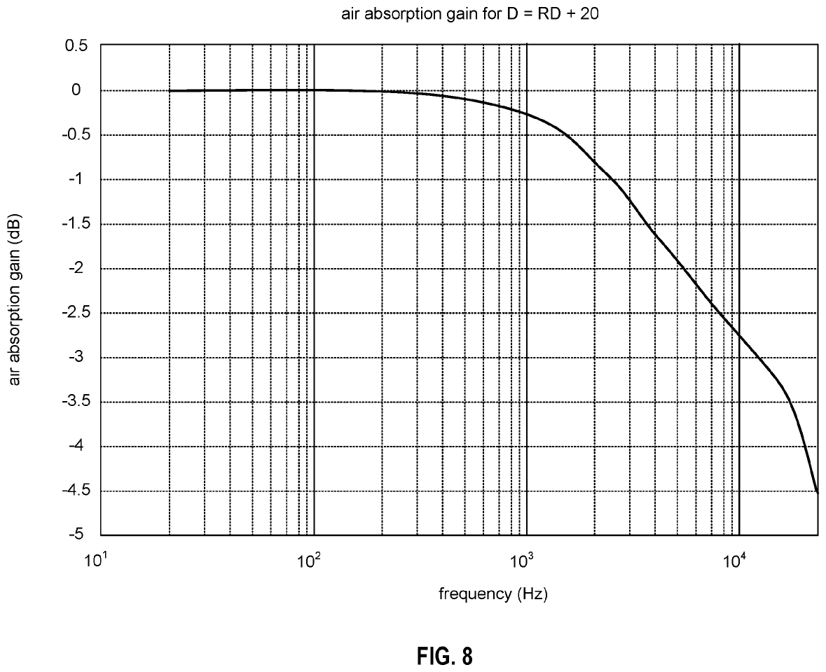

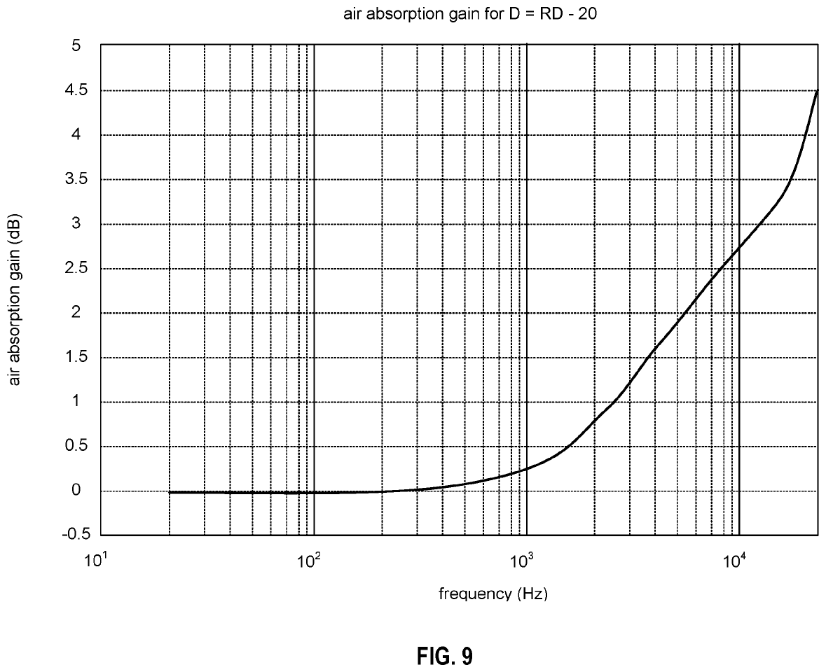

FIGS. 8 and 9 show an example (using the absorption coefficient curve of FIG. 5) of the frequency-dependent gain according to equations 2 and 5 that results at, respectively, a distance of RD+20 m (so 20 m further away from the source than the recording distance) and RD−20 m (so 20 m closer to source than the recording distance).

More generally, to allow for air absorption models different from equations (1) and (2), the air absorption filtering function may be expressed as:

$$AirAbs ( D , R D , f ) = \{ \begin{matrix}- AirAbs ( \vert {D}_{mod} \vert , f ) & - RD \leq {D}_{m o d} < 0 \\ AirAbs ( {D}_{mod} , f ) & {D}_{mod} \geq 0\end{matrix} , \qquad ( 6 )$$

or, equivalently:

$$AirAbs ( D , R D , f ) = \{ \begin{matrix}- AirAbs ( RD - D , f ) & 0 \leq D < RD \\ AirAbs ( D - RD , f ) & D \geq RD\end{matrix} . \qquad ( 7 )$$

Note that inversion of the air absorption filtering at distances to the source closer than the recording distance RD may amplify high frequency noise that may be present in the source signal (e.g., noise from the microphone and recording system used for recording the signal, or noise resulting from encoding and/or compression of the source signal). This may result in a noticeable and undesirable amplification of high-frequency noise, in particular in scenarios with a very large value of the recording distance and where the user is allowed to go much closer to the source than the recording distance. This may in many cases be addressed by applying a suitable noise-reduction algorithm to the signal after the air absorption processing according to one of the previous embodiments.

Another way to avoid excessive boost (i.e., positive gain) of high-frequency noise, that may be used instead of or in combination with noise reduction, is to limit the amount of boost of the high frequencies that is applied. For example, the boost may be limited to never exceed a maximum boost, e.g., 10 dB, so that never more than the maximum amount of boost is applied even if the air absorption model (e.g., equation 2) suggests a higher boost should be applied.

The latter solution, if implemented as a simple clipping of the boost, may have the disadvantage that the limiting of the high frequency boost becomes effective instantly when the maximum boost is reached, which may be perceived as unnatural. This may be avoided by smoothly introducing the boost limitation effect over a transition region such that as the distance to the source decreases, the corresponding relative increase of the boost decreases, with the resulting boost eventually saturating to the selected maximum boost at distances smaller than a certain distance from the source. This can be seen as applying a compression curve (soft-limiter) on the high frequency boost resulting from the air absorption function (e.g., equation 2).

In a variation of the previous embodiment, the amount of high frequency boost may be limited by applying a constant scaling factor between 0 and 1 (e.g., 0.5) to the amount of boost resulting from the air absorption function (e.g., equation 2) at distances closer than the recording distance. While this in principle does not prevent the boost to reach high levels, it may in many practical cases be sufficient to ensure an acceptable signal quality at all distances of interest.

However, in some cases the above embodiments may still not provide a satisfactory result, especially if the recording distance corresponding to the source signal was large. In such cases, the source signal recorded at the large recording distance may simply not contain much high frequency energy components corresponding to the physical source, since that high frequency source energy was filtered out during the physical propagation from the source to the distant recording position. Therefore, boosting the high frequencies of the recorded signal may not result in a good signal quality at these high frequencies in such cases.

To address this, some embodiments apply audio bandwidth extension techniques to synthesize the missing high frequency components. Essentially, these techniques apply some type of processing that synthesizes high frequency components from lower frequency components that are present in the signal. One technique is to apply some non-linear processing to the signal, which generates higher frequency harmonics of frequency components that are present in the signal. These generated high frequency components have a natural relationship to the frequency components that are present in the signal, since they are harmonically related to them and share the same temporal envelope. Another example of techniques that may be used to generate missing high frequency components is spectral band replication (SBR).

In some embodiments, any of these or other such bandwidth extension techniques may be used to synthesize additional high frequency components for the audio source signal, and may then be used instead of, or in combination with, boosting the high frequencies of the source signal itself when the distance is smaller than the recording distance. The mix of these two techniques (boosting and bandwidth extension) may be controlled by the amount of boost that is required (as per the used model, e.g., according to equation 2), and/or an analysis of how much relevant high frequency energy the source signal contains. For example, if only a modest boost is required and/or sufficient high frequency source signal energy is present in the source signal, then only boosting may be applied, while if a large boost is required and/or very little high frequency source signal energy is available, then mostly bandwidth extension may be applied.

Although some embodiments herein are exemplified for absorption due to sound propagation through air, other embodiments herein equally apply to absorption due to sound propagation through other media (e.g., water).

Moreover, although in the description and equations above attenuations and gains were expressed on a logarithmic dB scale, one or more of the equations may be expressed as linear-scale attenuations and gains. Furthermore, embodiments herein may equally apply to implementations using linear attenuation and/or gain parameters.

For example, on a logarithmic (dB) scale, each medium absorption gain value 23 in some embodiments described above may be calculated to be positive if the listening distance 30 is less than the recording distance 20 or negative if the listening distance 30 is greater than the recording distance 20. However, on a linear scale, each medium absorption gain value 23 may equivalently be calculated to be greater than one if the listening distance 30 is less than the recording distance 20 or less than one if the listening distance 30 is greater than the recording distance 20.

Note also that metadata 64 associated with an audio source herein may include one or more parameters (e.g., flag(s) to control behavior of the air absorption process according to some of the embodiments described above. For example, any or all of the below metadata elements may be used, and may, e.g., be included in a bitstream as additional source metadata parameters or as general system control parameters, to control the behavior of the air absorption process according to any of the embodiments described above.

In some embodiments, the metadata 64 includes a flag to control behavior when no explicit recording distance parameter is provided for a source. For example, the flag may indicate to the audio renderer 40 whether it should use any other suitable parameter that may be available to it as recording distance 20, or should just assume a recording distance of 0.

Alternatively or additionally, in some embodiments, the metadata 64 includes a flag to control whether the audio renderer 40 should estimate a recording distance for use in air absorption processing if no recording distance parameter is provided for a source.

Alternatively or additionally, in some embodiments, the metadata 64 includes a flag to control whether the audio renderer 40 should apply a positive air absorption gain (boost) at distances smaller than the recording distance.

Alternatively or additionally, in some embodiments, the metadata 64 includes a parameter indicating which parameter the renderer should use as recording distance parameter in the context of air absorption for a source, e.g., if multiple parameters are available that could potentially be used. For example, the parameter's possible values may include 0, 1, 2, 3, and 4. Here, a value of 0 means do not apply recording distance in air absorption processing, i.e., set recording distance to 0 (for the purpose of air absorption). A value of 1 means use explicit air absorption recording distance parameter. A vale of 2 means use general recording distance parameter distance. A value of 3 means use other available suitable parameter as recording distance. And a value of 4 means estimate the recording distance parameter from the audio signal.

Generally, then, some embodiments herein include a method for rendering an audio source. The method comprises obtaining a distance value D indicating a distance from a listening position to the audio source. The method further comprises obtaining a parameter indicating a recording distance RD associated with an audio signal corresponding to the audio source. The method also comprises deriving a gain value indicating an amount of air absorption at a frequency f, using the obtained distance and the obtained parameter. The method then comprises applying the derived gain value to the audio signal.

In some embodiments, deriving the gain value comprises calculating alpha(f)*(D−RD), wherein alpha(f) is a value of an absorption coefficient at the frequency f.

Alternatively or additionally, in some embodiments, deriving the gain value comprises deriving a modified distance D_mod using D and RD, and evaluating an air absorption model at D_mod.

Alternatively or additionally, in some embodiments, the derived gain value (when expressed on a logarithmic, dB, scale) is negative if D>RD, and positive if D<RD. This is the aspect that the air absorption is effectively inverted (i.e., the signal is boosted instead of dampened) at distances closer than the recording distance. Note that if the gain is expressed on a linear scale, then the derived gain value is smaller than 1 if D>RD and larger than 1 if D<RD.

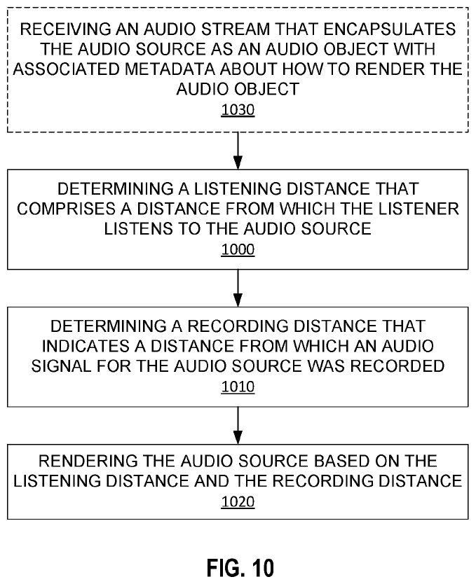

In view of the modifications and variations herein, FIG. 10 depicts a method of rendering an audio source 22 for a listener 50 in accordance with particular embodiments, e.g., as performed by an audio renderer 40. The method includes determining a listening distance 30 that comprises a distance from which the listener 50 listens to the audio source 22 (Block 1000). The method also includes determining a recording distance 20 that indicates a distance from which an audio signal 16 for the audio source 22 was recorded (Block 1010). The method also includes rendering the audio source 22 based on the listening distance 30 and the recording distance 20 (Block 1020).

In some embodiments, the method also includes receiving an audio stream 68 that encapsulates the audio source 22 as an audio object 65 with associated metadata 64 about how to render the audio object 65 (Block 1030).

In some embodiments, rendering the audio source 22 comprises rendering the audio source 22 to simulate medium absorption over the listening distance 30, given medium absorption over the recording distance 20 already represented in the audio signal 16.

In some embodiments, rendering the audio source 22 comprises controlling and/or applying medium absorption processing to the audio signal 16 based on the listening distance 30 and the recording distance 20.

In some embodiments, controlling medium absorption processing comprises making a decision as to whether or not to apply medium absorption processing to the audio signal 16, based on the listening distance 30 and the recording distance 20. In this case, controlling medium absorption processing also comprises applying, or refraining from applying, medium absorption processing to the audio signal 16 in accordance with the decision. In some embodiments, making the decision comprises making the decision to apply medium absorption processing to the audio signal 16 if the listening distance 30 is greater than the recording distance 20. In this case, making the decision also comprises making the decision to refrain from applying medium absorption processing to the audio signal 16 if the listening distance 30 is less than or equal to the recording distance 20.

In some embodiments, applying medium absorption processing comprises calculating one or more medium absorption gain values 23 as a function of the listening distance 30 and the recording distance 20. In this case, applying medium absorption processing also comprises applying the one or more medium absorption gain values 23 to the audio signal 16.

In some embodiments, calculating the one or more medium absorption gain values 23 comprises calculating the one or more medium absorption gain values 23 as a function of a difference 21 between the listening distance 30 and the recording distance 20.

In some embodiments, calculating the one or more medium absorption gain values 23 comprises calculating the one or more medium absorption gain values 23 to, on a logarithmic (dB) scale, each be zero if the listening distance 30 is less than the recording distance 20, and negative if the listening distance 30 is greater than the recording distance 20. Equivalently, on a linear scale, each medium absorption gain value 23 may be calculated to be one if the listening distance 30 is less than the recording distance 20 or less than one if the listening distance 30 is greater than the recording distance 20.

In other embodiments, calculating the one or more medium absorption gain values 23 comprises calculating the one or more medium absorption gain values 23 to, on a logarithmic (dB) scale, each be positive if the listening distance 30 is less than the recording distance 20, and negative if the listening distance 30 is greater than the recording distance 20. Equivalently, on a linear scale, each medium absorption gain value 23 may be calculated to be greater than one if the listening distance 30 is less than the recording distance 20 or less than one if the listening distance 30 is greater than the recording distance 20.

In some embodiments, the method further comprises, after applying the one or more medium absorption gain values 23 to the audio signal 16 to obtain a processed audio signal 16, applying noise reduction to the processed audio signal 16.

In some embodiments, the one or more medium absorption gain values 23 comprise one or more medium absorption gain values 23 for one or more respective frequencies.

In some embodiments, the one or more medium absorption gain values 23 comprise one or more values 23 of a gain function Gain(D,RD,f)=−AirAbs(D,RD,f) for the one or more respective frequencies f. In some embodiments, D is the listening distance 30 and RD is the recording distance 20. In some embodiments, AirAbs(D,RD,f)=α(f)*(D−RD), where α(f) is a value of an absorption coefficient at a frequency f.

In some embodiments, applying the one or more medium absorption gain values 23 to the audio signal 16 comprises, if the listening distance 30 is less than the recording distance 20, limiting or scaling the one or more medium absorption gain values 23, and applying the one or more medium absorption gain values 23, as limited or scaled, to the audio signal 16.

In some embodiments, limiting the one or more medium absorption gain values 23 comprises limiting the one or more medium absorption gain values 23 to not exceed a maximum gain value. In some embodiments, limiting or scaling the one or more medium absorption gain values 23 comprises limiting or scaling the one or more medium absorption gain values 23 to an extent that depends on the listening distance 30.

In some embodiments, the method further comprises, before applying the one or more medium absorption gain values 23, applying audio bandwidth extension to the audio signal 16 in order to synthesize one or more high frequency components in the audio signal 16.

In some embodiments, the audio source 22 comprises the audio signal 16 and metadata 64 describing how to render the audio source 22 from the audio signal 16. In some embodiments, determining the recording distance 20 comprises determining the recording distance 20 from one or more parameters 20P included in the metadata 64. In some embodiments, the one or more parameters 20P include a recording distance parameter that explicitly indicates the recording distance 20. In some embodiments, the one or more parameters 20P include a medium absorption recording distance parameter that explicitly indicates a distance over which medium absorption is already represented in the audio signal 16.

In some embodiments, the audio signal 16 is a recording of a source audio signal 16 as recorded from the recording distance 20. In some embodiments, determining the recording distance 20 comprises determining the recording distance 20 based on comparing one or more characteristics of the audio signal 16 to the same one or more characteristics of the source audio signal 16.

In some embodiments, determining the recording distance 20 comprises determining the recording distance 20 based on comparing one or more characteristics of the audio signal 16 to the same one or more characteristics of a reference audio signal. In some embodiments, the audio source 22 comprises the audio signal 16 and metadata 64 describing how to render the audio source 22 from the audio signal 16. In some embodiments, determining the recording distance 20 comprises determining the recording distance 20 according to an ordering of candidate determination options. In some embodiments, the candidate determination options include at least a medium absorption recording distance parameter in the metadata 64 that explicitly indicates a distance over which medium absorption is already represented in the audio signal 16. In other embodiments, the candidate determination options additionally or alternatively include at least a recording distance parameter in the metadata 64 that explicitly indicates the recording distance 20 corresponding to the audio signal 16. In yet other embodiments, the candidate determination options additionally or alternatively include at least a comparison of one or more characteristics of the audio signal 16 to the same one or more characteristics of a reference audio signal. In some embodiments, the medium absorption recording distance parameter is ordered by the ordering before the recording distance parameter. In some embodiments, the recording distance parameter is ordered by the ordering before the comparison.

In some embodiments, the audio source 22 comprises one or more audio channels. In other embodiments, the audio source 22 alternatively comprises one or more audio objects 65. In yet other embodiments, the audio source 22 alternatively comprises one or more higher-order ambisonic, HOA, signals. In yet other embodiments, the audio source 22 alternatively comprises any combination thereof.

In some embodiments, rendering the audio source 22 is performed as part of rendering audio of an extended reality application.

In some embodiments, rendering the audio source 22 comprises rendering the audio source 22 into an audio output signal 42. In some embodiments, the method further comprises providing the audio output signal 42 for playback to the listener 50. In some embodiments, the audio output signal 42 is a binaural signal.

In some embodiments, the method further comprises receiving an audio stream 68 that encapsulates the audio source 22 as an audio object 65 with associated metadata 64 about how to render the audio object 65. In some embodiments, the audio stream 68 is an MPEG-H 3D audio stream or MPEG-I Immersive Audio stream.

In some embodiments, the method is performed by audio rendering equipment.

In some embodiments, the method is performed by an audio renderer 40.

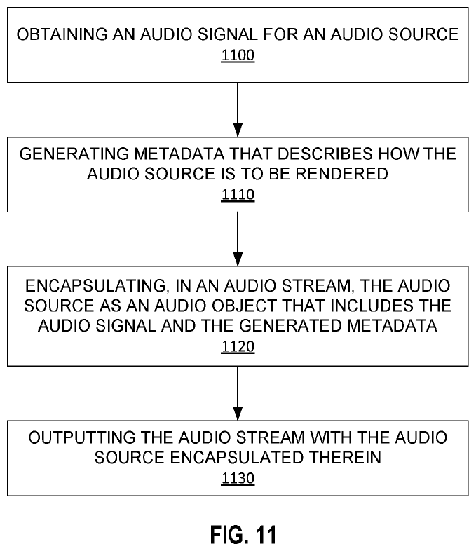

FIG. 11 depicts a method in accordance with other particular embodiments, e.g., as performed by an audio encoder 60. The method includes obtaining an audio signal 16 for an audio source 22 (Block 1100). The method also includes generating metadata 64 that describes how the audio source 22 is to be rendered (Block 1110). In some embodiments, the metadata 64 is generated to include one or more parameters 20P that indicate a recording distance 20, where the recording distance 20 indicates a distance from which the audio signal 16 for the audio source 22 was recorded. The method also includes encapsulating, in an audio stream 68, the audio source 22 as an audio object 65 that includes the audio signal 16 and the generated metadata 64 (Block 1120). The method also includes outputting (e.g., transmitting) the audio stream 68 with the audio source 22 encapsulated therein (Block 1130).

In some embodiments, the one or more parameters 20P include a recording distance parameter that explicitly indicates the recording distance 20.

In some embodiments, the one or more parameters 20P include a medium absorption recording distance parameter that explicitly indicates a distance over which medium absorption is already represented in the audio signal 16.

In some embodiments, the audio source 22 is an audio source 22 of an extended reality application.

In some embodiments, the audio stream 68 is an MPEG-H 3D audio stream or MPEG-I Immersive Audio stream.

In some embodiments, the method is performed by an audio encoder 60.

Embodiments herein also include corresponding apparatuses. Embodiments herein for instance include an audio renderer 40 configured to perform any of the steps of any of the embodiments described above for the audio renderer 40.

Embodiments also include an audio renderer 40 comprising processing circuitry and power supply circuitry. The processing circuitry is configured to perform any of the steps of any of the embodiments described above for the audio renderer 40. The power supply circuitry is configured to supply power to the audio renderer 40.

Embodiments further include an audio renderer 40 comprising processing circuitry. The processing circuitry is configured to perform any of the steps of any of the embodiments described above for the audio renderer 40. In some embodiments, the audio renderer 40 further comprises communication circuitry, e.g., configured to receive an audio stream.

Embodiments further include an audio renderer 40 comprising processing circuitry and memory. The memory contains instructions executable by the processing circuitry whereby the audio renderer 40 is configured to perform any of the steps of any of the embodiments described above for the audio renderer 40.

Embodiments moreover include a user equipment (UE). The UE comprises an antenna configured to send and receive wireless signals. The UE also comprises radio front-end circuitry connected to the antenna and to processing circuitry, and configured to condition signals communicated between the antenna and the processing circuitry. The UE may further comprise an audio renderer configured to perform any of the steps of any of the embodiments described above for the audio renderer 40. In some embodiments, the UE also comprises an input interface connected to the processing circuitry and configured to allow input of information into the UE to be processed by the processing circuitry. The UE may comprise an output interface connected to the processing circuitry and configured to output information from the UE that has been processed by the processing circuitry. The UE may also comprise a battery connected to the processing circuitry and configured to supply power to the UE.

Embodiments herein also include an audio encoder 60 configured to perform any of the steps of any of the embodiments described above for the audio encoder 60.

Embodiments also include an audio encoder 60 comprising processing circuitry and power supply circuitry. The processing circuitry is configured to perform any of the steps of any of the embodiments described above for the audio encoder 60. The power supply circuitry is configured to supply power to the audio encoder 60.

Embodiments further include an audio encoder 60 comprising processing circuitry. The processing circuitry is configured to perform any of the steps of any of the embodiments described above for the audio encoder 60. In some embodiments, the audio encoder 60 further comprises communication circuitry.

Embodiments further include an audio encoder 60 comprising processing circuitry and memory. The memory contains instructions executable by the processing circuitry whereby the audio encoder 60 is configured to perform any of the steps of any of the embodiments described above for the audio encoder 60.

More particularly, the apparatuses described above may perform the methods herein and any other processing by implementing any functional means, modules, units, or circuitry. In one embodiment, for example, the apparatuses comprise respective circuits or circuitry configured to perform the steps shown in the method figures. The circuits or circuitry in this regard may comprise circuits dedicated to performing certain functional processing and/or one or more microprocessors in conjunction with memory. For instance, the circuitry may include one or more microprocessor or microcontrollers, as well as other digital hardware, which may include digital signal processors (DSPs), special-purpose digital logic, and the like. The processing circuitry may be configured to execute program code stored in memory, which may include one or several types of memory such as read-only memory (ROM), random-access memory, cache memory, flash memory devices, optical storage devices, etc. Program code stored in memory may include program instructions for executing one or more telecommunications and/or data communications protocols as well as instructions for carrying out one or more of the techniques described herein, in several embodiments. In embodiments that employ memory, the memory stores program code that, when executed by the one or more processors, carries out the techniques described herein.

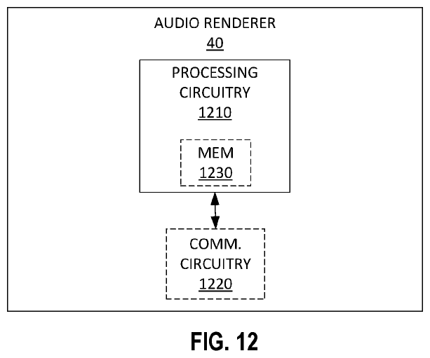

FIG. 12 for example illustrates an audio renderer 40 as implemented in accordance with one or more embodiments. As shown, the audio renderer 40 includes processing circuitry 1210. The processing circuitry 1210 is configured to perform processing described above, e.g., in FIG. 10, such as by executing instructions stored in memory 1230. The processing circuitry 1210 in this regard may implement certain functional means, units, or modules. In some embodiments, the audio renderer 40 further comprises communication circuitry 1220 configured to transmit and/or receive information to and/or from one or more other nodes, e.g., via any communication technology.

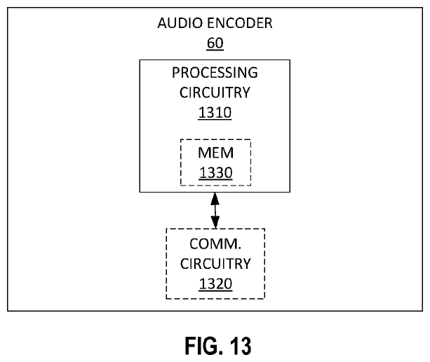

FIG. 13 illustrates an audio encoder 60 as implemented in accordance with one or more embodiments. As shown, the audio encoder 60 includes processing circuitry 1310. The processing circuitry 1310 is configured to perform processing described above, e.g., in FIG. 11, such as by executing instructions stored in memory 1330. The processing circuitry 1310 in this regard may implement certain functional means, units, or modules. In some embodiments, the audio encoder 60 further comprises communication circuitry 1320 configured to transmit and/or receive information to and/or from one or more other nodes, e.g., via any communication technology.

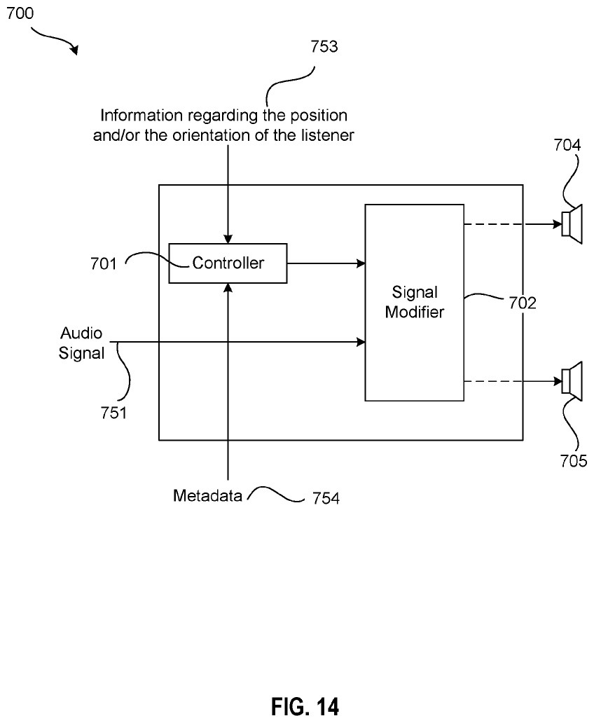

FIG. 14 illustrates an exemplary system 700 in which the audio renderer 40 may be implemented in accordance with one or more other embodiments, e.g., for producing sound for an XR scene. System 700 includes a controller 701, a signal modifier 702 for modifying an audio signal 751, a left speaker 704, and a right speaker 705. While one audio signal and two speakers are shown in this example, other embodiments may include any number of audio signals and any number of speakers.

Controller 701 may be configured to receive one or more parameters and to trigger signal modifier 702 to perform modifications on audio signal 751 based on the received parameters, e.g., increasing or decreasing the volume level. The received parameters include (1) information 753 regarding the position of the listener (e.g., direction and distance to an audio source) and (2) metadata 754 regarding an audio object. The metadata may for example include a parameter indicating the recording distance herein and/or include a parameter from which the recording distance is determinable. The metadata 754 may be an example of metadata 64 in FIG. 4. In this context, the audio renderer 40 herein may be implemented by the controller 701 and/or the signal modifier 702.

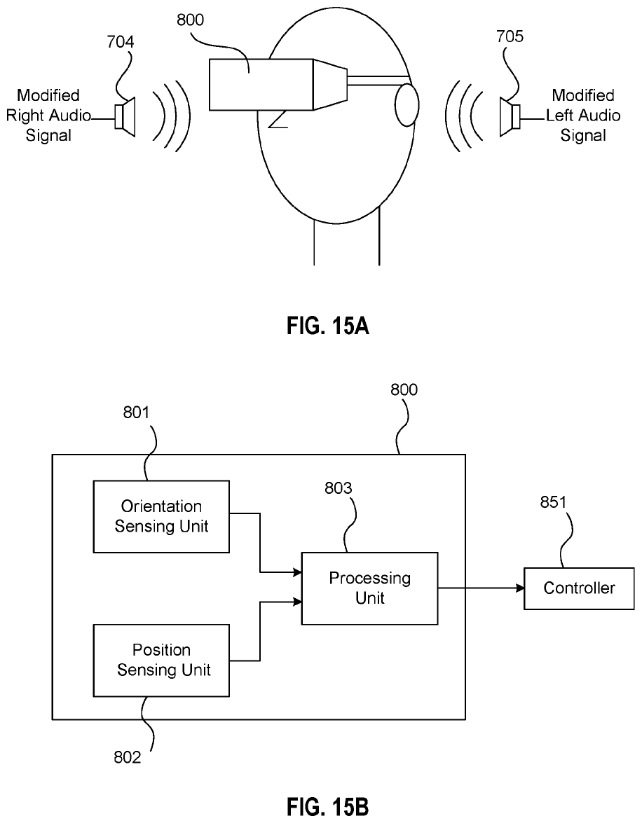

In some embodiments, information 753 may be provided from one or more sensors included in an XR system 800 illustrated in FIG. 15A. As shown, XR system 800 is configured to be worn by the listener. As shown in FIG. 8B, the XR system 800 may comprise an orientation sensing unit 801, a position sensing unit 802, and a processing unit 803 coupled to controller 851 of system 800. Orientation sensing unit 801 is configured to detect a change in the orientation of the listener and provide information regarding the detected change to the processing unit 803. In some embodiments, processing unit 803 determines the absolute orientation (in relation to some coordinate system) given the detected change in orientation detected by orientation sensing unit 801. There could also be different systems for determination of orientation and position, e.g., a system using lighthouse trackers (lidar). In one embodiment, orientation sensing unit 801 may determine the absolute orientation given the detected change in orientation. In this case, the processing unit 803 may simply multiplex the absolute orientation data from orientation sensing unit 801 and the absolute positional data from positioning sensing unit 802. In some embodiments, orientation sensing unit 801 may comprise one or more accelerometers and/or one or more gyroscopes. Note that one or more of the units 801, 802, and/or 803 may be implemented as one or more respective circuits.

Those skilled in the art will also appreciate that embodiments herein further include corresponding computer programs.

A computer program comprises instructions which, when executed on at least one processor of an audio renderer 40, cause the audio renderer 40 to carry out any of the respective processing described above. A computer program in this regard may comprise one or more code modules corresponding to the means or units described above.

Embodiments further include a carrier containing such a computer program. This carrier may comprise one of an electronic signal, optical signal, radio signal, or computer readable storage medium.

In this regard, embodiments herein also include a computer program product stored on a non-transitory computer readable (storage or recording) medium and comprising instructions that, when executed by a processor of an audio renderer 40, cause the audio renderer 40 to perform as described above.

Embodiments further include a computer program product comprising program code portions for performing the steps of any of the embodiments herein when the computer program product is executed by an audio renderer 40. This computer program product may be stored on a computer readable recording medium.

In other embodiments, a computer program comprises instructions which, when executed on at least one processor of an audio encoder 40, cause the audio encoder 40 to carry out any of the respective processing described above. A computer program in this regard may comprise one or more code modules corresponding to the means or units described above.

Embodiments further include a carrier containing such a computer program. This carrier may comprise one of an electronic signal, optical signal, radio signal, or computer readable storage medium.

In this regard, embodiments herein also include a computer program product stored on a non-transitory computer readable (storage or recording) medium and comprising instructions that, when executed by a processor of an audio encoder 40, cause the audio encoder 40 to perform as described above.

Embodiments further include a computer program product comprising program code portions for performing the steps of any of the embodiments herein when the computer program product is executed by an audio encoder 40. This computer program product may be stored on a computer readable recording medium.

Example embodiments of the techniques and apparatus described herein include, but are not limited to, the following enumerated examples:

### Group A Embodiments

A1. A method of rendering an audio source for a listener, the method comprising:
determining a listening distance that comprises a distance from which the listener listens to the audio source;
determining a recording distance that indicates a distance from which an audio signal for the audio source was recorded; and
rendering the audio source based on the listening distance and the recording distance.

A2. The method of embodiment A1, wherein rendering the audio source comprises rendering the audio source to simulate medium absorption over the listening distance, given medium absorption over the recording distance already represented in the audio signal.

A3. The method of any of embodiments A1-A2, wherein rendering the audio source comprises controlling and/or applying medium absorption processing to the audio signal based on the listening distance and the recording distance.

A4. The method of embodiment A3, wherein controlling medium absorption processing comprises:
making a decision as to whether or not to apply medium absorption processing to the audio signal, based on the listening distance and the recording distance; and
applying, or refraining from applying, medium absorption processing to the audio signal in accordance with the decision.

A5. The method of embodiment A4, wherein making the decision comprises:
making the decision to apply medium absorption processing to the audio signal if the listening distance is greater than the recording distance; and
making the decision to refrain from applying medium absorption processing to the audio signal if the listening distance is less than or equal to the recording distance.

A6. The method of embodiment A3, wherein applying medium absorption processing comprises:
calculating one or more medium absorption gain values as a function of the listening distance and the recording distance; and
applying the one or more medium absorption gain values to the audio signal.

A7. The method of embodiment A6, wherein calculating the one or more medium absorption gain values comprises calculating the one or more medium absorption gain values as a function of a difference between the listening distance and the recording distance.

A8. The method of embodiment A7, wherein calculating the one or more medium absorption gain values comprises calculating the one or more medium absorption gain values to, on a logarithmic (dB) scale, each be:
zero if the listening distance is less than the recording distance; and
negative if the listening distance is greater than the recording distance.

A9. The method of embodiment A7, wherein calculating the one or more medium absorption gain values comprises calculating the one or more medium absorption gain values to, on a logarithmic (dB) scale, each be:
positive if the listening distance is less than the recording distance; and
negative if the listening distance is greater than the recording distance.

A10. The method of embodiment A9, further comprising, after applying the one or more medium absorption gain values to the audio signal to obtain a processed audio signal, applying noise reduction to the processed audio signal.

A11. The method of any of embodiments A6-A10, wherein the one or more medium absorption gain values comprise one or more medium absorption gain values for one or more respective frequencies.

A12. The method of embodiment A11, wherein the one or more medium absorption gain values comprise one or more values of a gain function Gain(D,RD,f)=−AirAbs(D,RD,f) for the one or more respective frequencies f, wherein D is the listening distance and RD is the recording distance.

A13. The method of embodiment A12, wherein AirAbs(D,RD,f)=α(f)+ (D−RD), where α(f) is a value of an absorption coefficient at a frequency f.

A14. The method of any of embodiments A11-A13, wherein applying the one or more medium absorption gain values to the audio signal comprises, if the listening distance is less than the recording distance:
limiting or scaling the one or more medium absorption gain values; and
applying the one or more medium absorption gain values, as limited or scaled, to the audio signal.

A15. The method of embodiment A14, wherein limiting the one or more medium absorption gain values comprises limiting the one or more medium absorption gain values to not exceed a maximum gain value.

A16. The method of embodiment A14, wherein limiting or scaling the one or more medium absorption gain values comprises limiting or scaling the one or more medium absorption gain values to an extent that depends on the listening distance.

A17. The method of any of embodiments A11-A16, further comprising, before applying the one or more medium absorption gain values, applying audio bandwidth extension to the audio signal in order to synthesize one or more high frequency components in the audio signal.

A18. The method of any of embodiments A1-A17, wherein the audio source comprises the audio signal and metadata describing how to render the audio source from the audio signal, and wherein determining the recording distance comprises determining the recording distance from one or more parameters included in the metadata.

A19. The method of embodiment A18, wherein the one or more parameters include a recording distance parameter that explicitly indicates the recording distance.

A20. The method of embodiment A18, wherein the one or more parameters include a medium absorption recording distance parameter that explicitly indicates a distance over which medium absorption is already represented in the audio signal.

A21. The method of any of embodiments A1-A16, wherein the audio signal is a recording of a source audio signal as recorded from the recording distance, and wherein determining the recording distance comprises determining the recording distance based on comparing one or more characteristics of the audio signal to the same one or more characteristics of the source audio signal.

A22. The method of any of embodiments A1-A16, wherein determining the recording distance comprises determining the recording distance based on comparing one or more characteristics of the audio signal to the same one or more characteristics of a reference audio signal.

A23. The method of any of embodiments A21-A22, wherein the one or more characteristics include a spectrum and/or level.

A24. The method of any of embodiments A1-A23, wherein the audio source comprises the audio signal and metadata describing how to render the audio source from the audio signal, wherein determining the recording distance comprises determining the recording distance according to an ordering of candidate determination options, wherein the candidate determination options include at least two or more of:
a medium absorption recording distance parameter in the metadata that explicitly indicates a distance over which medium absorption is already represented in the audio signal;
a recording distance parameter in the metadata that explicitly indicates the recording distance corresponding to the audio signal; and
a comparison of one or more characteristics of the audio signal to the same one or more characteristics of a reference audio signal;
wherein the medium absorption recording distance parameter is ordered by the ordering before the recording distance parameter, and wherein the recording distance parameter is ordered by the ordering before the comparison.

A25. The method of any of embodiments A1-A24, wherein the audio source comprises:
one or more audio channels;
one or more audio objects;
one or more higher-order ambisonics, HOA, signals; or
any combination thereof.

A26. The method of any of embodiments A1-A25, wherein rendering the audio source is performed as part of rendering audio of an extended reality application.

A27. The method of any of embodiments A1-A26, wherein rendering the audio source comprises rendering the audio source into an audio output signal and wherein the method further comprising providing the audio output signal for playback to the listener.

A28. The method of embodiment A27, wherein the audio output signal is a binaural signal.

A29. The method of any of embodiments A1-A28, further comprising receiving an audio stream that encapsulates the audio source as an audio object with associated metadata about how to render the audio object.

A30. The method of embodiment A29, wherein the audio stream is an MPEG-H 3D audio stream or MPEG-I Immersive Audio stream.

A31. The method of any of embodiments A1-A30, wherein the method is performed by audio rendering equipment.

A32. The method of any of embodiments A1-A31, wherein the method is performed by an audio renderer.

### Group B Embodiments

B1. A method comprising:
obtaining an audio signal for an audio source;
generating metadata that describes how the audio source is to be rendered, wherein the metadata is generated to include one or more parameters that indicate a recording distance, wherein the recording distance indicates a distance from which the audio signal for the audio source was recorded;
encapsulating, in an audio stream, the audio source as an audio object that includes the audio signal and the generated metadata; and
outputting the audio stream with the audio source encapsulated therein.

B2. The method of embodiment B1, wherein the one or more parameters include a recording distance parameter that explicitly indicates the recording distance.

B3. The method of embodiment B1, wherein the one or more parameters include a medium absorption recording distance parameter that explicitly indicates a distance over which medium absorption is already represented in the audio signal.

B4. The method of any of embodiments B1-B3, wherein the audio source is an audio source of an extended reality application.

B5. The method of any of embodiments B1-B4, wherein the audio stream is an MPEG-H 3D audio stream or MPEG-I Immersive Audio stream.

B6. The method of any of embodiments B1-B5, wherein the method is performed by an audio encoder.

### Group C Embodiments

C1. An audio renderer configured to perform any of the steps of any of the Group A embodiments.

C2. An audio renderer comprising processing circuitry configured to perform any of the steps of any of the Group A embodiments.

C3. An audio renderer comprising:
communication circuitry; and
processing circuitry configured to perform any of the steps of any of the Group A embodiments.

C4. An audio renderer comprising:
processing circuitry configured to perform any of the steps of any of the Group A embodiments; and
power supply circuitry configured to supply power to the communication device.

C5. An audio renderer comprising:
processing circuitry and memory, the memory containing instructions executable by the processing circuitry whereby the communication device is configured to perform any of the steps of any of the Group A embodiments.

C6. The audio renderer of any of embodiments C1-C5, wherein the audio renderer is an audio renderer of a communication device.

C7. A user equipment (UE) comprising:
an antenna configured to send and receive wireless signals;
radio front-end circuitry connected to the antenna and to processing circuitry, and configured to condition signals communicated between the antenna and the processing circuitry;
an audio renderer configured to perform any of the steps of any of the Group A embodiments;
an input interface connected to the processing circuitry and configured to allow input of information into the UE to be processed by the processing circuitry;
an output interface connected to the processing circuitry and configured to output information from the UE that has been processed by the processing circuitry; and
a battery connected to the processing circuitry and configured to supply power to the UE.

C8. A computer program comprising instructions which, when executed by at least one processor of an audio renderer, causes the audio renderer to carry out the steps of any of the Group A embodiments.

C9. A carrier containing the computer program of embodiment C7, wherein the carrier is one of an electronic signal, optical signal, radio signal, or computer readable storage medium.

C10. An audio encoder configured to perform any of the steps of any of the Group B embodiments.

C11. An audio encoder comprising processing circuitry configured to perform any of the steps of any of the Group B embodiments.

C12. An audio encoder comprising:
communication circuitry; and
processing circuitry configured to perform any of the steps of any of the Group B embodiments.

C13. An audio encoder comprising:
processing circuitry configured to perform any of the steps of any of the Group B embodiments;
power supply circuitry configured to supply power to the audio encoder.

C14. An audio encoder comprising:
processing circuitry and memory, the memory containing instructions executable by the processing circuitry whereby the audio encoder is configured to perform any of the steps of any of the Group B embodiments.

C15. A computer program comprising instructions which, when executed by at least one processor of an audio encoder, causes the audio encoder to carry out the steps of any of the Group B embodiments.

C16. A carrier containing the computer program of embodiment C15, wherein the carrier is one of an electronic signal, optical signal, radio signal, or computer readable storage medium.

### REFERENCES

1. ANSI Standard S1-26:1995, “Calculation Of The Absorption Of Sound By The Atmosphere”
2. ISO 9613-1:1996., “Acoustics—Attenuation of sound during propagation outdoors—Part 1: Calculation of the absorption of sound by the atmosphere”
3. ISO-IECJTC1-SC29-WG6_N0131: Working Draft of ISO 23090-4:202 #(X) MPEG-I Immersive Audio, version 1, 2022.
4. ISO-IECJTC1-SC29-WG6_N0054: MPEG-I Immersive Audio Encoder Input Format, 2021

1.-22. (canceled)

23. A method of rendering an audio source for a listener, the method comprising:
determining a listening distance that comprises a distance from which the listener listens to the audio source;
determining a recording distance that indicates a distance from which an audio signal for the audio source was recorded; and
rendering the audio source based on the listening distance and the recording distance, by:
calculating one or more medium absorption gain values such that:
on a logarithmic (dB) scale, each medium absorption gain value is positive if the listening distance is less than the recording distance or negative if the listening distance is greater than the recording distance; or
on a linear scale, each medium absorption gain value is greater than one if the listening distance is less than the recording distance or less than one if the listening distance is greater than the recording distance; and
applying the one or more medium absorption gain values to the audio signal.

24. The method of claim 23, wherein applying the one or more medium absorption gain values to the audio signal simulates medium absorption over the listening distance, given medium absorption over the recording distance already represented in the audio signal.

25. The method of claim 23, wherein rendering the audio source further comprises, after applying the one or more medium absorption gain values to the audio signal to obtain a processed audio signal, applying noise reduction to the processed audio signal.

26. The method of claim 23, wherein calculating the one or more medium absorption gain values comprises calculating the one or more medium absorption gain values as a function of a difference between the listening distance and the recording distance.

27. The method of claim 23, wherein the one or more medium absorption gain values comprise one or more medium absorption gain values for one or more respective frequencies, wherein the one or more medium absorption gain values comprise one or more values of a gain function Gain(D,RD,f)=−AirAbs(D,RD,f) for the one or more respective frequencies f, wherein D is the listening distance and RD is the recording distance.

28. The method of claim 27, wherein AirAbs(D,RD,f)=α(f)*(D−RD), where α(f) is a value of an absorption coefficient at a frequency f.

29. The method of claim 23, wherein applying the one or more medium absorption gain values to the audio signal comprises, if the listening distance is less than the recording distance:
limiting or scaling the one or more medium absorption gain values; and
applying the one or more medium absorption gain values, as limited or scaled, to the audio signal.

30. The method of claim 29, wherein limiting the one or more medium absorption gain values comprises limiting the one or more medium absorption gain values to not exceed a maximum gain value.

31. The method of claim 29, wherein limiting or scaling the one or more medium absorption gain values comprises limiting or scaling the one or more medium absorption gain values to an extent that depends on the listening distance.

32. The method of claim 23, wherein the audio source comprises the audio signal and metadata describing how to render the audio source from the audio signal, and wherein determining the recording distance comprises determining the recording distance from one or more parameters included in the metadata.

33. The method of claim 32, wherein the one or more parameters include:
a recording distance parameter that explicitly indicates the recording distance; or
a medium absorption recording distance parameter that explicitly indicates a distance over which medium absorption is already represented in the audio signal.

34. The method of claim 23, wherein rendering the audio source is performed as part of rendering audio of an extended reality application.

35. The method of claim 23, wherein rendering the audio source comprises rendering the audio source into an audio output signal and wherein the method further comprising providing the audio output signal for playback to the listener, wherein the audio output signal is a binaural signal.

36. The method of claim 23, further comprising receiving an audio stream that encapsulates the audio source as an audio object with associated metadata about how to render the audio object, wherein the audio stream is an MPEG-H 3D audio stream or MPEG-I Immersive Audio stream.

37. An audio renderer rendering an audio source for a listener, the audio renderer comprising:
processing circuitry and memory, the memory containing instructions executable by the processing circuitry whereby the audio renderer is configured to:
determine a listening distance that comprises a distance from which the listener listens to the audio source;
determine a recording distance that indicates a distance from which an audio signal for the audio source was recorded; and
render the audio source based on the listening distance and the recording distance, by:
calculating one or more medium absorption gain values such that:
on a logarithmic (dB) scale, each medium absorption gain value is positive if the listening distance is less than the recording distance or negative if the listening distance is greater than the recording distance; or
on a linear scale, each medium absorption gain value is greater than one if the listening distance is less than the recording distance or less than one if the listening distance is greater than the recording distance; and
applying the one or more medium absorption gain values to the audio signal.

38. The audio renderer of claim 37, the processing circuitry configured to apply the one or more medium absorption gain values to the audio signal to simulate medium absorption over the listening distance, given medium absorption over the recording distance already represented in the audio signal.

39. The audio renderer of claim 37, the processing circuitry configured to render the audio source further by, after applying the one or more medium absorption gain values to the audio signal to obtain a processed audio signal, applying noise reduction to the processed audio signal.

40. The audio renderer of claim 37, the processing circuitry configured to calculate the one or more medium absorption gain values by calculating the one or more medium absorption gain values as a function of a difference between the listening distance and the recording distance.

41. The audio renderer of claim 37, the processing circuitry configured to apply the one or more medium absorption gain values to the audio signal by, if the listening distance is less than the recording distance:
limiting or scaling the one or more medium absorption gain values; and
applying the one or more medium absorption gain values, as limited or scaled, to the audio signal.

42. A communication device comprising the audio renderer of claim 37.
